(19) United States
(12) Patent Application Publication
(10) Pub. No.: US 2026/0150515 A1
(43) Pub. Date: May 28, 2026

(54) DISPLAY PANEL, DISPLAY DEVICE, AND METHOD FOR PREPARING DISPLAY PANEL

(71) Applicants: Hefei Visionox Technology Co., Ltd., Hefei (CN); Visionox Technology Inc., Kunshan (CN)

(72) Inventors: Zhiwei ZHOU, Hefei (CN); Peng QIN, Kunshan (CN); Yang YANG, Hefei (CN); Lu ZHANG, Kunshan (CN)

(73) Assignees: Hefei Visionox Technology Co., Ltd., Hefei (CN); Visionox Technology Inc., Kunshan (CN)

(21) Appl. No.: 19/373,608

(22) Filed: Oct. 29, 2025

(30) Foreign Application Priority Data
Oct. 29, 2024 (CN) 202411528285.6

(51) Int. Cl. H10K 59/122; H10K 59/12; H10K 59/80

(52) U.S. Cl. CPC H10K 59/122; H10K 59/1201; H10K 59/873

(57) ABSTRACT

This application provides a display panel, a display device, and a method for preparing the display panel. The display panel includes a substrate, a pixel definition layer, and an isolation structure. The pixel definition layer is located on one side of the substrate and includes a first pixel definition portion and a second pixel definition portion. The first pixel definition portion encloses a plurality of pixel openings, and the second pixel definition portion is located on a side of the first pixel definition portion away from the plurality of pixel openings.

### CROSS-REFERENCE TO RELATED APPLICATIONS

The present application claims priority to Chinese Patent Application No. 202411528285.6, titled “DISPLAY PANEL, DISPLAY DEVICE, AND METHOD FOR PREPARING DISPLAY PANEL” and filed on Oct. 29, 2024, which is hereby incorporated by reference in its entirety.

### FIELD

The present application belongs to the field of display technology, and more particularly, relates to a display panel, a display device, and a method for preparing a display panel.

### BACKGROUND

Flat panel display devices based on technologies such as Organic Light Emitting Diodes (OLEDs) are widely used in various consumer electronic products, including mobile phones, televisions, laptops, and desktop computers, due to their advantages such as high image quality, energy efficiency, thin profile, and broad application range. They have become mainstream in display devices.

However, the performance of current OLED display products needs improvement.

### SUMMARY

To achieve the above objective, the technical solution adopted in the present application is as follows.

In a first aspect, a display panel is provided, comprising a substrate, a pixel definition layer, and an isolation structure. The pixel definition layer is located on one side of the substrate and includes a first pixel definition portion and a second pixel definition portion. The first pixel definition portion encloses a plurality of pixel openings, and the second pixel definition portion is located on a side of the first pixel definition portion away from the plurality of pixel openings. The isolation structure is located on a side of the pixel definition layer away from the substrate and includes a first end portion and a second end portion. The first end portion contacts a surface of the second pixel definition portion away from the substrate, and the second end portion is located on a side of the first end portion away from the substrate. The isolation structure encloses a plurality of isolation openings, and the pixel opening is located within the isolation opening.

In a direction perpendicular to the plane of the substrate, a maximum distance from a surface of the first pixel definition portion away from the substrate to the substrate is defined as a first distance, and a distance from a surface of the second pixel definition portion away from the substrate to the substrate is defined as a second distance, wherein the first distance is less than the second distance.

In a second aspect, the present application further provides a method for preparing a display panel, the method comprising: forming a pixel definition material layer on one side of a substrate, and forming an isolation material layer on a side of the pixel definition material layer away from the substrate; etching and patterning the isolation material layer to form an isolation structure, wherein the isolation structure encloses a plurality of isolation openings; etching and patterning the pixel definition material layer to form a first pixel definition portion and a second pixel definition portion, wherein the first pixel definition portion encloses a plurality of pixel openings, and the second pixel definition portion is located on a side of the first pixel definition portion away from the plurality of pixel openings; the pixel opening is located within the isolation opening, and the isolation structure includes a first end portion and a second end portion, wherein the first end portion contacts a surface of the second pixel definition portion away from the substrate, and the second end portion is located on a side of the first end portion away from the substrate; in a direction perpendicular to the plane of the substrate, a maximum distance from a surface of the first pixel definition portion away from the substrate to the substrate is defined as a first distance, and a distance from a surface of the second pixel definition portion away from the substrate to the substrate is defined as a second distance, wherein the first distance is less than the second distance.

In a third aspect, the present application further provides a display device, comprising the aforementioned display panel.

The display panel provided in the present application can be processed by etching the isolation structure and the pixel definition layer to form the first pixel definition portion and the second pixel definition portion with different morphologies in the direction perpendicular to the plane of the substrate. This ensures that potential residue issues of the isolation structure during the etching of the pixel definition layer are overcome, thereby avoiding display abnormalities in the display panel caused by residue of the isolation structure. Additionally, the display panel can adjust the surface of the pixel definition layer away from the substrate to have a stepped morphology, resulting in a relatively smooth step-like structure with gradual height changes. This facilitates continuous bridging of the cathode, improves the reliability of the display panel, and enhances the display performance of the display panel.

### BRIEF DESCRIPTION OF THE DRAWINGS

FIG. 1 is a schematic plan view of a display panel provided by an embodiment of the present application;

FIG. 2 is an enlarged structural view of area A in the display panel shown in FIG. 1;

FIG. 3 is a first schematic cross-sectional view of the display panel shown in FIG. 2;

FIG. 4 is an enlarged structural view of area B in FIG. 3;

FIG. 5 is a second schematic cross-sectional view of the display panel shown in FIG. 2;

FIG. 6 is an enlarged structural view of area C in FIG. 5;

FIG. 7 is a third schematic cross-sectional view of the display panel shown in FIG. 2;

FIG. 8 is an enlarged structural view of area D in FIG. 7;

FIG. 9 is a schematic flowchart of a method for preparing a display panel provided by an embodiment of the present application;

FIG. 10A to FIG. 10G are schematic diagrams of the preparation process of a display panel provided by an embodiment of the present application; and

FIG. 11 is a schematic plan view of a display device provided by an embodiment of the present application.

In the drawings, the reference numerals are as follows: 1, substrate; 2, pixel definition layer; 201, pixel opening; 21, first pixel definition portion; 211, first sub-portion; 21101, first surface; 212, second sub-portion; 21201, second surface; 22, second pixel definition portion; 2201, second sidewall; 3, isolation structure; 301, first end portion; 302, second end portion; 303, isolation opening; 31, support portion; 311, first support portion; 31101, first sidewall; 312, second support portion; 32, crown portion; 4, first electrode layer; 5, light-emitting functional layer; 6, second electrode layer; 7, encapsulation layer; 701, encapsulation unit; 71, first encapsulation portion; 72, second encapsulation portion; 73, third encapsulation portion; 10, display panel; 100, display device.

### DETAILED DESCRIPTION OF THE EMBODIMENTS

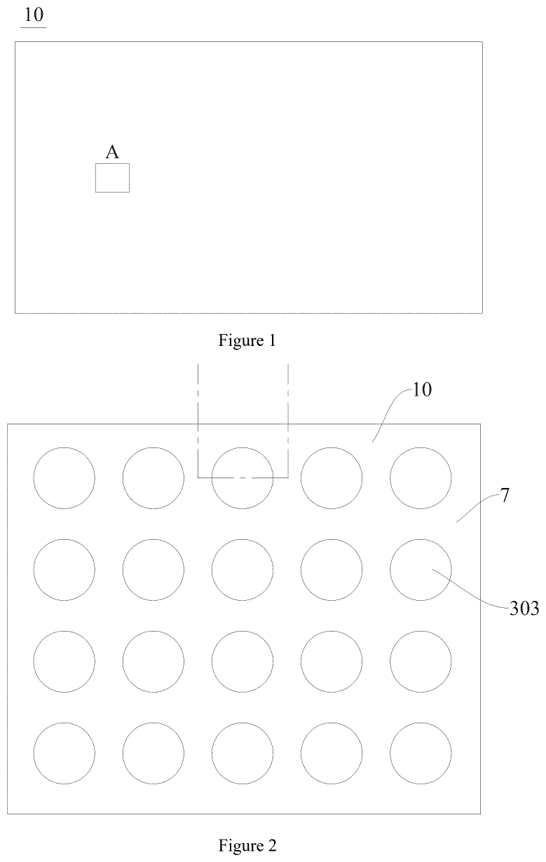

Please refer to FIG. 1 to FIG. 2. The display panel 10 includes a substrate 1, a pixel definition layer 2, and an isolation structure 3. The pixel definition layer 2 is located on the substrate 1 and defines a plurality of pixel openings 201. The isolation structure 3 is located on a side of the pixel definition layer 2 away from the substrate 1. The isolation structure 3 includes a first end portion 301 and a second end portion 302, the second end portion 302 is located on a side of the first end portion 301 away from the substrate 1. The isolation structure 3 defines a plurality of isolation openings 303, the isolation opening 303 corresponds to and communicates with the pixel opening 201. The pixel opening 201 is located within the isolation opening 303.

The pixel definition layer 2 is an inorganic layer, which can be used to define the pixel boundaries, ensuring mutual independence between individual pixels. Additionally, it can block moisture from the substrate 1, preventing external factors such as water and oxygen from corroding the relevant film layers located on the side of the pixel definition portion away from the substrate 1.

The content related to the isolation structure 3 mentioned below is further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A for reference.

The pixel definition layer 2 includes a first pixel definition portion 21 and a second pixel definition portion 22. The first pixel definition portion 21 encloses and forms the pixel openings 201, while the second pixel definition portion 22 is connected to the first pixel definition portion 21 and surrounds the first pixel definition portion 21. In other words, the second pixel definition portion 22 is located on a side of the first pixel definition portion 21 away from the pixel openings 201.

Since the isolation structure 3 defines the isolation openings 303, the isolation structure 3 located on the side of the pixel definition layer 2 away from the substrate 1 can be connected to the pixel definition layer 2 via the second pixel definition portion 22. That is, the isolation structure 3 contacts a surface of the second pixel definition portion 22 away from the substrate 1 through the first end portion 301.

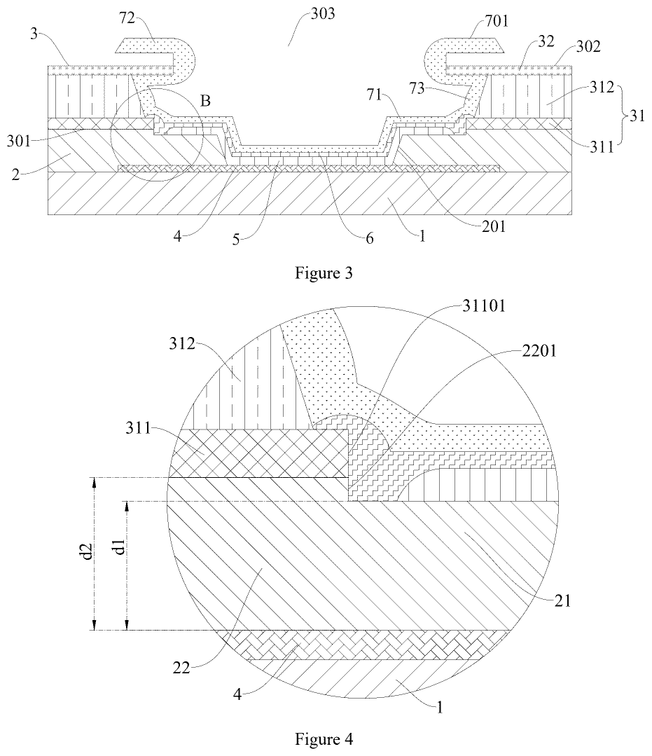

In a direction perpendicular to the plane of the substrate 1, the maximum distance from a surface of the first pixel definition portion 21 away from the substrate 1 to the substrate 1 is defined as a first distance, and the distance from a surface of the second pixel definition portion 22 away from the substrate 1 to the substrate 1 is defined as a second distance. The first distance is less than the second distance. Please refer to FIG. 3 and FIG. 4.

When the surface of the first pixel definition portion 21 away from the substrate 1 is parallel to the plane of the substrate 1, the aforementioned maximum distance refers to the distance between the surface of the first pixel definition portion 21 away from the substrate 1 and the substrate 1. When the surface of the first pixel definition portion 21 away from the substrate 1 has a stepped structure, the aforementioned maximum distance refers to the distance between the surface of the first pixel definition portion 21 farthest from the substrate 1 and the substrate 1.

In FIG. 4, d1 represents the first distance, and d2 represents the second distance. It can be clearly seen from the figure that d2>d1, meaning the thickness of the second pixel definition portion 22 is greater than the thickness of the first pixel definition portion 21. This indicates that the first pixel definition portion 21, which constitutes the pixel definition layer 2, is thinned relative to the second pixel definition portion 22, resulting in the surfaces of the first pixel definition portion 21 and the second pixel definition portion 22 away from the substrate 1 being located on different planes. During processing, the isolation structure 3 that may adhere to the surface of the first pixel definition portion 21 is completely etched away due to the thinning of the first pixel definition portion 21. Therefore, the solution provided in this embodiment effectively addresses the issue of residual isolation structure 3, reduces the likelihood of display abnormalities in the display panel 10 caused by residual isolation structure 3, improves the display performance of the display panel 10, and enhances the reliability and usability of the display panel 10.

In a direction perpendicular to the plane of the substrate 1, the initial thickness of the pixel definition layer 2 is substantially uniform at all positions. After thinning a portion of the pixel definition layer 2 exposed by the isolation openings 303 to form the first pixel definition portion 21 and the second pixel definition portion 22, the thickness of the first pixel definition portion 21 is less than that of the second pixel definition portion 22.

It should be noted that the thickness difference between the first pixel definition portion 21 and the second pixel definition portion 22 can be adjusted as needed, as long as a spacing difference exists between the plane of the first end portion 301 of the isolation structure 3 and the plane of the end of the first pixel definition portion 21 away from the substrate 1.

To further mitigate the residual isolation structure 3 and ensure that the thinning process of the pixel definition layer 2 effectively removes residual portions of the isolation structure 3, in some embodiments, please refer to FIG. 3 to FIG. 6, the orthographic projection of the first end portion 301 of the isolation structure 3 on the substrate 1 is located outside the orthographic projection of the first pixel definition portion 21 on the substrate 1.

Specifically, the orthographic projection outline of the first end portion 301 on the substrate 1 is set to exactly overlap with the orthographic projection outline of the first pixel definition portion 21 on the substrate 1. Please refer to FIG. 3 and FIG. 4, where the orthographic projection of the first end portion 301 on the substrate 1 exactly overlaps with the orthographic projection of the second pixel definition portion 22 on the substrate 1.

Please refer to FIG. 4, where the first end portion 301 of the isolation structure 3 is attached to the surface of the second pixel definition portion 22 facing away from the substrate 1, and their dimensions are consistent.

Additionally, the side of the isolation structure 3 near the isolation opening 303 has a first sidewall 31101, which is connected to the first end portion 301. The side of the second pixel definition portion 22 near the isolation opening 303 has a second sidewall 2201 (the second sidewall 2201 is formed on the side of the second pixel definition portion 22 facing away from the substrate 1 and protruding relative to the first pixel definition portion 21). At least a portion of the first sidewall 31101 and at least a portion of the second sidewall 2201 on the same side of the isolation opening 303 are connected and lie on the same plane or curved surface.

Please refer to FIG. 4, where the first sidewall 31101 and the second sidewall 2201 lie on the same plane, and both are perpendicular to the plane of the substrate 1. Therefore, the orthographic projection outline of the first end portion 301 on the substrate 1 can exactly overlap with the orthographic projection outline of the first pixel definition portion 21 on the substrate 1.

The spacing difference between the first spacing d1 and the second spacing d2 labeled in FIG. 4 represents the thinning extent of the first pixel definition portion 21 relative to the second pixel definition portion 22. Without affecting the insulating barrier function of the first pixel definition portion 21 and the structure and function of other related film layers, the specific dimensions and differences of d1 and d2 can be adaptively adjusted according to actual needs.

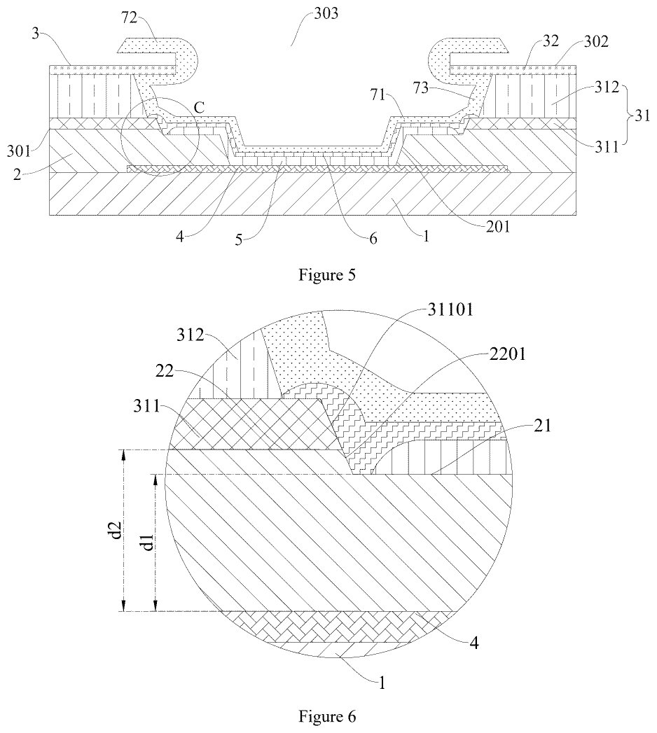

Specifically, the orthographic projection of the first end portion 301 on the substrate 1 can also be set to have an interval from the orthographic projection of the first pixel definition portion 21 on the substrate 1. Please refer to FIG. 5 and FIG. 6, where there is a certain gap between the orthographic projection outline of the first end portion 301 on the substrate 1 and the orthographic projection outline of the second pixel definition portion 22 on the substrate 1.

In this case, the orthographic projection of the first end portion 301 on the substrate 1 lies within the range of the orthographic projection of the second pixel definition portion 22 on the substrate 1.

The connection between the first sidewall 31101 and the second sidewall 2201 is a smooth transition. During actual processing, the shapes of the first sidewall 31101 and the second sidewall 2201 are affected by processing precision. For example, when using a dry etching process to thin the first pixel definition portion 21, since the vertical etching rate is greater than the lateral etching rate, the first sidewall 31101 and the second sidewall 2201 may form the shapes shown in FIG. 5 and FIG. 6.

Please refer to FIG. 6, where it can be seen that, compared to FIG. 4, the first sidewall 31101 and the second sidewall 2201 lie on the same plane, but this plane is inclined relative to the plane of the substrate 1.

In the direction parallel to the plane of the substrate, the distance between the side of the same plane facing away from the substrate and the edge of the pixel opening 201 is greater than the distance between the side of the same plane near the substrate and the edge of the pixel opening 201.

Specifically, there is an angle between the same plane and the direction perpendicular to the plane of the substrate, and this angle is between 0 and 90 degrees. Therefore, there is a certain gap between the orthographic projection outline of the first end portion 301 on the substrate 1 and the orthographic projection outline of the second end portion 302 on the substrate 1. However, it should be noted that the orthographic projection of the first sidewall 31101 on the substrate 1 and the orthographic projection of the second sidewall 2201 on the substrate 1 are connected and can exactly fill this gap.

Specifically, the angle ranges from 50° to 80°, and its specific value range can be adjusted according to actual needs. For example, the angle can be any value among 50°, 55°, 60°, 65°, 70°, 75°, 80°, etc.

In some embodiments, the form of the isolation structure 3 is shown in FIG. 3 and FIG. 5.

In the direction perpendicular to the plane of the substrate, the cross-sectional shape of the isolation structure 3 is similar to a rectangle or trapezoid, or the cross-sectional shape of the isolation structure 3 may also exhibit a “wide at the top and narrow at the bottom” form.

In some embodiments, the orthographic projection of the first end portion 301 of the isolation structure 3 on the substrate 1 lies within the range of the orthographic projection of the second end portion 302 on the substrate 1.

Please refer to FIG. 3, where the orthographic projection of the first pixel definition portion 21 on the substrate 1 partially overlaps with the orthographic projection of the second end portion 302 on the substrate 1. Further, a portion of the orthographic projection of the first pixel definition portion 21 on the substrate 1 lies within the range of the orthographic projection of the second end portion 302 on the substrate 1. It should be noted that the orthographic projection of the first pixel definition portion 21 on the substrate 1 always remains non-overlapping with the orthographic projection of the first end portion 301 on the substrate 1 or only their outlines overlap.

Specifically, the isolation structure 3 includes a crown portion 32 and a support portion 31 stacked sequentially, with the crown portion 32 located on the side of the support portion 31 facing away from the substrate 1. The first end portion 301 is provided at the end of the support portion 31 facing away from the crown portion 32, and the second end portion 302 is provided at the end of the crown portion 32 facing away from the support portion 31.

Specifically, the orthographic projection of the support portion 31 on the substrate 1 lies within the range of the orthographic projection of the crown portion 32 on the substrate 1. The orthographic projection of the first pixel definition portion 21 on the substrate 1 partially overlaps with the orthographic projection of the crown portion 32 on the substrate 1.

In some embodiments, the support portion 31 of the isolation structure 3 may be a single-layer structure or a multi-layer structure.

When the support portion 31 is a multi-layer structure, it can be configured to include a first support portion 311 and a second support portion 312 stacked sequentially, with the second support portion 312 located on the side of the first support portion 311 facing away from the substrate 1. The first end portion 301 is provided at the end of the first support portion 311 facing away from the second support portion 312. The orthographic projection of the second support portion 312 on the substrate 1 lies within the range of the orthographic projection of the first support portion 311 on the substrate 1.

Specifically, please refer to FIG. 3, where the orthographic projection of the first support portion 311 on the substrate 1 overlaps with the orthographic projection of the second pixel definition portion 22 on the substrate 1.

Specifically, referring to FIG. 5, the orthographic projection of the first support portion 311 on the substrate 1 is located within the orthographic projection range of the second pixel definition portion 22 on the substrate 1.

Referring to FIG. 3 and FIG. 5, the orthographic projection of the first pixel definition portion 21 on the substrate 1 partially overlaps with the orthographic projection of the crown portion 32 on the substrate 1.

In some embodiments, the sidewall of the second support portion 312 facing the isolation opening 303 is offset away from the isolation opening 303 relative to the first sidewall 31101 of the first support portion 311, such that the cross-sectional sidewall of the isolation structure 3 exhibits an overhanging shape.

Certainly, in other similar embodiments, the dimensions and projection relationships among the first support portion 311, the second support portion 312, and the crown portion 32 may be adaptively adjusted according to actual processing requirements.

In some embodiments, the cross-sectional shapes of the first support portion 311 and the crown portion 32 are similar to rectangles or trapezoids, while the cross-sectional shape of the second support portion 312 is similar to a trapezoid.

In some embodiments, the first support portion 311, the second support portion 312, and the crown portion 32 are integrally formed structures or are formed by stacking different material layers.

Specifically, the material of the crown portion 32 includes metallic titanium, forming a titanium metal layer; the material of the second support portion 312 includes metallic aluminum, forming an aluminum metal layer; the material of the first support portion 311 includes one of titanium nitride and molybdenum nitride, and taking titanium nitride as an example, the first support portion 311 is a titanium nitride layer.

In other embodiments, the surface of the first pixel definition portion 21 facing away from the substrate 1 is a complete planar surface or a segmented planar surface with a stepped structure, depending on the morphology of the isolation structure 3.

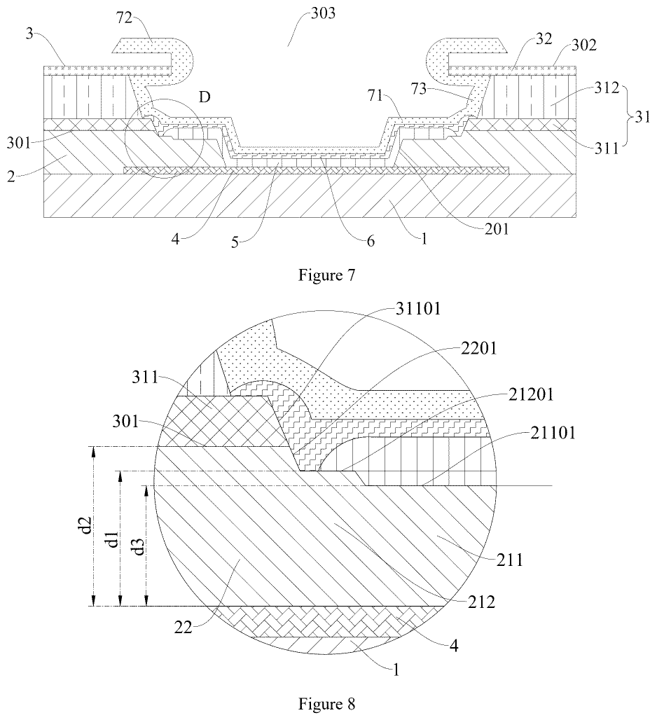

Specifically, referring to FIG. 7 to FIG. 8, the first pixel definition portion 21 includes a first sub-portion 211 and a second sub-portion 212, with the first sub-portion 211 enclosing the pixel openings 201. The second sub-portion 212 is located between the first sub-portion 211 and the second pixel definition portion 22. The surface of the first sub-portion 211 facing away from the substrate 1 is a first surface 21101, and the surface of the second sub-portion 212 facing away from the substrate 1 is a second surface 21201. In a direction perpendicular to the plane of the substrate 1, the second surface 21201 is located on the side of the first surface 21101 facing away from the substrate 1.

Since the second surface 21201 is located on the side of the first surface 21101 facing away from the substrate 1, the distance from the second surface 21201 to the substrate 1 is the aforementioned first distance d1, and the distance from the first surface 21101 to the substrate 1 is a third distance d3, with the third distance d3 being smaller than the first distance d1.

Referring to FIG. 7, the second sub-portion 212 surrounds the first sub-portion 211, and the second pixel definition portion 22 surrounds the second sub-portion 212. Since the second surface 21201 is located on the side of the first surface 21101 facing away from the substrate 1, the plane of the first surface 21101 and the plane of the second surface 21201 are two distinct planes with a spacing between them. The first sub-portion 211 is further thinned relative to the second sub-portion 212, resulting in the first surface 21101 and the second surface 21201 on the surface of the first pixel definition portion 21 facing away from the substrate 1 being located on planes of different heights. Correspondingly, the surfaces formed by the first sub-portion 211, the second sub-portion 212, and the second pixel definition portion 22 on the side facing away from the substrate 1 constitute a stepped structure.

In FIG. 8, d1 denotes the first spacing, d2 denotes the second spacing, and d3 denotes the third spacing. The difference between d1 and d2 represents the degree of thinning of the second sub-portion 212 in the first pixel definition portion 21 relative to the second pixel definition portion 22, while the difference between d3 and d1 represents the degree of thinning of the first sub-portion 211 in the first pixel definition portion 21 relative to the second sub-portion 212. Without affecting the barrier insulation function of the first pixel definition portion 21 and the structure and function of other related film layers, the dimensions of d1, d2, and d3, as well as the differences between any two of them, may be adaptively adjusted according to actual needs.

Referring to FIG. 7 to FIG. 8, the orthographic projection of the first sub-portion 211 on the substrate 1 is interleaved with the orthographic projection of the isolation structure 3 on the substrate 1, meaning that the orthographic projection of the first sub-portion 211 on the substrate 1 is located outside the orthographic projection of the second end portion 302 of the isolation structure 3 on the substrate 1.

Specifically, the outer contour of the orthographic projection of the first sub-portion 211 on the substrate 1 may be set to exactly overlap with the outer contour of the orthographic projection of the second end portion 302 on the substrate 1, or the orthographic projection of the first sub-portion 211 on the substrate 1 may be arranged at intervals with the orthographic projection of the second end portion 302 on the substrate 1.

Further, referring to FIG. 7, the orthographic projection of the second sub-portion 212 on the substrate 1 is located outside the orthographic projection of the first end portion 301 on the substrate 1. Specifically, the outer contour of the orthographic projection of the second sub-portion 212 on the substrate 1 may be set to exactly overlap with the outer contour of the orthographic projection of the first end portion 301 on the substrate 1, or the orthographic projection of the second sub-portion 212 on the substrate 1 may be arranged at intervals with the orthographic projection of the first end portion 301 on the substrate 1.

Similarly, the orthographic projection of the second sub-portion 212 on the substrate 1 is located outside the orthographic projection of the first support portion 311 on the substrate 1.

It should be noted that the orthographic projection of the second sub-portion 212 on the substrate 1 at least partially overlaps with the orthographic projection of the second end portion 302 on the substrate 1. This means that the orthographic projection of the second sub-portion 212 on the substrate 1 may exactly fall within the range of the orthographic projection of the second end portion 302 on the substrate 1, or the orthographic projection of the end of the second sub-portion 212 close to the second pixel definition portion 22 on the substrate 1 may fall within the range of the orthographic projection of the second end portion 302 on the substrate 1, while at least part of the orthographic projection of the end of the second sub-portion 212 close to the first sub-portion 211 on the substrate 1 may be located outside the range of the orthographic projection of the second end portion 302 on the substrate 1 or exactly on the outer contour of the orthographic projection of the second end portion 302 on the substrate 1.

Similarly, the orthographic projection of the second sub-portion 212 on the substrate 1 at least partially overlaps with the orthographic projection of the crown portion 32 on the substrate 1.

The aforementioned structure not only enables effective removal of residual structures of the isolation structure 3 through partial thinning of the pixel definition layer 2, but also adjusts the height variation trend on different positions of the surface of the pixel definition layer 2 away from the substrate 1 to become gentler, improving the magnitude of height difference variation at different positions of the film layer. Such structural design facilitates the smooth attachment and connection of other film layers with the isolation structure 3 in subsequent processing steps, helping to enhance the performance and reliability of the display panel 10.

For example, when an electrode for connecting with the isolation structure 3 is provided on the side of the pixel definition layer 2 away from the substrate 1, the stepped surface described above is beneficial for improving the continuity of the electrode, enabling the electrode to connect with the isolation structure 3 more conveniently and reliably.

Correspondingly, referring to FIG. 8, the first pixel definition portion 21, after thinning treatment, forms the first sub-portion 211 and the second sub-portion 212, wherein the thickness of the first sub-portion 211 is less than that of the second sub-portion 212.

It should be noted that the thickness difference between the first sub-portion 211 and the second sub-portion 212 can be adaptively adjusted according to actual needs, as long as it is ensured that the thickness difference between the first sub-portion 211 and the second sub-portion 212 is less than the thickness difference between the first sub-portion 211 and the second pixel definition portion 22.

For the display panel 10 provided in the embodiments of this application, to facilitate the thinning treatment of the pixel definition layer 2 and considering the display effect of the display panel 10, the orthographic projection of the pixel opening 201 on the substrate 1 is located within the orthographic projection of the isolation opening 303 on the substrate 1.

Referring to FIGS. 3-8, the display panel 10 further includes a first electrode layer 4, a light-emitting functional layer 5, a second electrode layer 6, and an encapsulation layer 7, at least partially located within the isolation opening 303.

Specifically, the first electrode layer 4 is located between the substrate 1 and the pixel definition layer 2, with at least a portion of the first electrode layer 4 exposed through the pixel opening 201. The orthographic projection of the first electrode layer 4 on the substrate 1 at least partially overlaps with the orthographic projection of the support portion 31 on the substrate 1.

In some embodiments, the orthographic projection of the first electrode layer 4 on the substrate 1 partially overlaps with the orthographic projection of the second pixel definition portion 22 on the substrate 1.

Specifically, the orthographic projection of the first pixel definition portion 21 on the substrate 1 is located within the orthographic projection of the first electrode layer 4 on the substrate 1; the orthographic projection of the first electrode layer 4 on the substrate 1 partially overlaps with the orthographic projection of the second pixel definition portion 22 on the substrate 1.

Specifically, the orthographic projection of the first electrode layer 4 on the substrate 1 at least partially overlaps with the orthographic projection of the second support portion 312 on the substrate 1.

In the case where the first pixel definition portion 21 includes the first sub-portion 211 and the second sub-portion 212, the thickness relationship between the first sub-portion 211 and the second sub-portion 212 or their respective spacing relationships with the substrate 1 can be referred to as described above and will not be repeated here.

Specifically, the light-emitting functional layer 5 and the second electrode layer 6 are sequentially stacked on the side of the first electrode layer 4 away from the substrate 1.

It should be noted that the light-emitting functional layer 5 is located on the side of the pixel definition layer 2 away from the substrate 1 and within the isolation opening 303. The light-emitting functional layer 5 passes through the pixel opening 201 to connect with the first electrode layer 4. The light-emitting functional layer 5 does not contact the sidewall of the isolation structure 3 facing the isolation opening 303.

Specifically, the light-emitting functional layer 5 may be connected to the surface of the first pixel definition portion 21 away from the substrate 1; further, the light-emitting functional layer 5 may only be connected to the first sub-portion 211.

In some embodiments, the orthographic projection of the pixel opening 201 on the substrate 1 is located within the orthographic projection of the light-emitting functional layer 5 on the substrate 1.

The isolation structure 3 utilizes the isolation opening 303 to isolate the light-emitting functional layers 5 located in different isolation openings 303, ensuring that the light-emitting functional layers 5 in different isolation openings 303 remain independent and non-conductive to each other.

Specifically, the light-emitting functional layer 5 may be processed from organic small molecule light-emitting materials, complex light-emitting materials, and high molecular polymers. Different light-emitting functional layers 5 can be used to emit light of different colors. Generally, there are three types of light-emitting functional layers 5, respectively used to emit red, green, and blue light.

The second electrode layer 6 is located on the side of the light-emitting functional layer 5 away from the substrate 1 and within the isolation opening 303. The second electrode layer 6 is connected to at least a portion of the sidewall of the isolation structure 3 facing the isolation opening 303.

Specifically, the second electrode layer 6 may be connected to the support portion 31 of the isolation structure 3. In this case, the orthographic projection of the second electrode layer 6 on the substrate 1 partially overlaps with the orthographic projection of the support portion 31 on the substrate 1.

Specifically, the second electrode layer 6 may be connected to the first support portion 311 of the isolation structure 3. In this case, the orthographic projection of the second electrode layer 6 on the substrate 1 partially overlaps with the orthographic projection of the first support portion 311 on the substrate 1.

Specifically, the second electrode layer 6 may be simultaneously connected to both the first support portion 311 and the second support portion 312 of the isolation structure 3. In this case, the orthographic projection of the second electrode layer 6 on the substrate 1 partially overlaps with the orthographic projection of the second support portion 312 on the substrate 1.

The preparation and processing methods of the first electrode layer 4, the second electrode layer 6, and the light-emitting functional layer 5 are existing techniques and will not be repeated here.

In some embodiments, the first electrode layer 4 may be an anode layer, and the second electrode layer 6 may be a cathode layer; of course, the second electrode layer 6 may also be adjusted to be an anode layer as needed, in which case the first electrode layer 4 would be a cathode layer.

The structure of the encapsulation layer 7 is further described below:

In some embodiments, at least a portion of the encapsulation layer 7 is located within the isolation opening 303 and covers the second electrode layer 6.

Referring to FIGS. 3, 5, and 7, the encapsulation layer 7 includes a plurality of spaced encapsulation units 701. The encapsulation units 701 are arranged in one-to-one correspondence with the isolation openings 303.

Any encapsulation unit 701 includes a first encapsulation portion 71, a second encapsulation portion 72, and a third encapsulation portion 73, wherein the first encapsulation portion 71 is located on a side of the second electrode away from the substrate 1 and covers the second electrode, the second encapsulation portion 72 is located on a side of the isolation structure 3 away from the substrate 1, and the third encapsulation portion 73 covers a sidewall of the isolation structure 3 facing the isolation opening 303. The third encapsulation portion 73 connects the first encapsulation portion 71 and the second encapsulation portion 72.

It should be noted that there is a gap between the second encapsulation portion 72 and the surface of the second end portion 302 of the isolation structure 3, thereby, the second encapsulation portion 72 is suspended relative to the isolation structure 3.

In any one of the isolation openings 303, the encapsulation unit 701 composed of the first encapsulation portion 71, the second encapsulation portion 72, and the third encapsulation portion 73 is a continuous film structure.

After applying the encapsulation layer 7 to encapsulate the isolation opening 303, other film structures need to be provided on the side of the encapsulation layer 7 away from the substrate 1 to further planarize and encapsulate the display panel 10.

Specifically, at least one film structure among a planarization layer, an organic encapsulation film layer, an inorganic encapsulation film layer, a touch layer, an organic adhesive layer, and a cover plate is further provided on the side of the encapsulation layer 7 away from the substrate 1.

Taking the planarization layer as an example, the material of the planarization layer may include at least one of an organic material and an inorganic material. For example, an organic polymer (such as polyimide, acrylic resin, etc.) or an inorganic material (such as silicon oxide, silicon nitride, etc.).

The planarization layer made of an organic material can be prepared by techniques such as IJP (Ink-Jet Printing). Part of the planarization layer can flow into the isolation opening 303 and improve the flatness of the display panel 10 by filling the isolation opening 303, while also providing certain protection to the related film layers located below it.

It can be understood that the display panel 10 provided in the embodiments of the present application can perform thinning treatment on the area of the pixel definition layer 2 that may be attached to the isolation structure 3 by etching the isolation structure 3 and the pixel definition layer 2, so as to overcome the residue problem of the isolation structure 3 and avoid display abnormalities of the display panel 10 caused by the residue of the isolation structure 3. In addition, the display panel 10 can also adjust the surface of the pixel definition layer 2 away from the substrate 1 to have a stepped shape, so that the surface of the pixel definition layer 2 is a step-like structure with relatively gentle height changes, which helps to achieve continuous connection of the cathode, improves the reliability of the display panel 10, and helps to enhance the reliability of the display panel 10 and improve the display effect of the display panel 10.

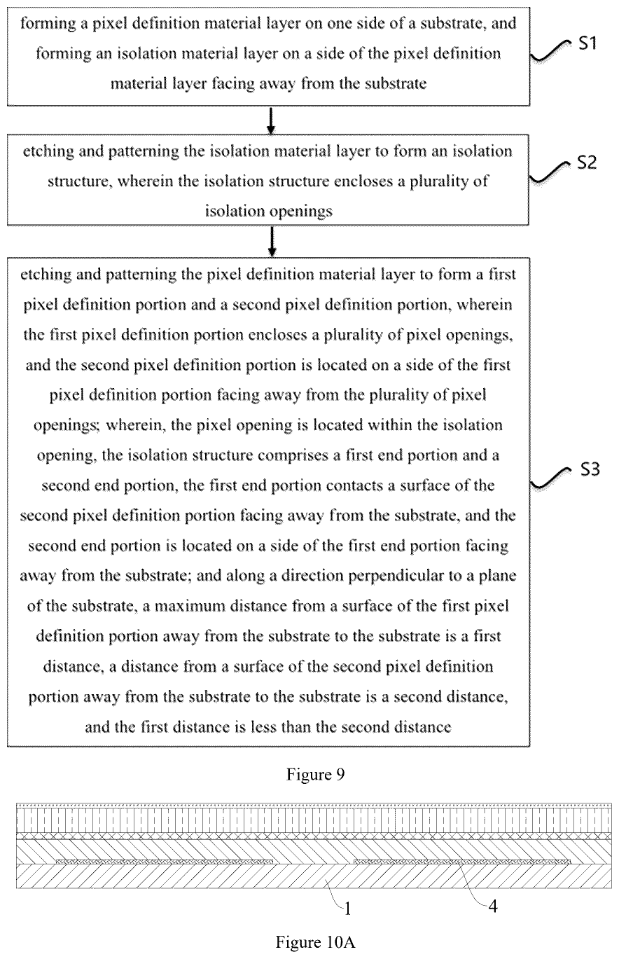

In a second aspect, the present application also provides a method for preparing a display panel 10. Please refer to FIG. 9.

The above method can be used to prepare the display panel 10 described above. The method includes:
Step S1: Prepare a pixel definition material layer on one side of the substrate 1, and prepare an isolation material layer on the side of the pixel definition material layer away from the substrate 1;
Step S2: Perform etching and patterning on the isolation material layer to form an isolation structure 3, wherein the isolation structure 3 encloses a plurality of isolation openings 303;
Step S3: Perform etching and patterning on the pixel definition material layer to form a first pixel definition portion 21 and a second pixel definition portion 22, wherein the first pixel definition portion 21 encloses a plurality of pixel openings, and the second pixel definition portion 22 is located on the side of the first pixel definition portion 21 away from the pixel opening 201.

The pixel opening 201 is located within the isolation opening 303, and the isolation structure 3 includes a first end portion 301 and a second end portion 302, wherein the first end portion 301 is in contact with the surface of the second pixel definition portion 22 away from the substrate 1, and the second end portion 302 is located on the side of the first end portion 301 away from the substrate 1; Wherein, along a direction perpendicular to the plane of the substrate 1, the maximum distance from the surface of the first pixel definition portion 21 away from the substrate 1 to the substrate 1 is a first distance, and the distance from the surface of the second pixel definition portion 22 away from the substrate 1 to the substrate 1 is a second distance, and the first distance is less than the second distance.

In this preparation method, the specific structure of the display panel 10 is the same as that of any embodiment of the above display panel 10, and will not be repeated here.

For this preparation method, after the isolation structure 3 forms the isolation openings 303, at least part of the structure of the pixel definition material layer exposed relative to the isolation openings 303 can be thinned to form the first pixel definition portion 21 and the second pixel definition portion 22, wherein the first pixel definition portion 21 exposed relative to the isolation openings 303 is thinned, and its thickness becomes smaller, while the thickness of the second pixel definition portion 22 covered by the isolation structure 3 remains unchanged. In this process, the isolation structure 3 that may be attached to the surface of the first pixel definition portion 21 away from the substrate 1 can be completely removed as the first pixel definition portion 21 is thinned.

In the above step S1, the step of preparing the isolation material layer on the side of the pixel definition material layer away from the substrate 1 includes:
Step S101: Prepare a first support material layer on the side of the pixel definition material layer away from the substrate 1;
Step S102: Prepare a second support material layer on the side of the first support material layer away from the substrate 1;
Step S103: Prepare a crown material layer on the side of the second support material layer away from the substrate 1.

Since the isolation structure 3 is a multilayer structure, the isolation material layer used to prepare the isolation structure 3 is also a multilayer structure.

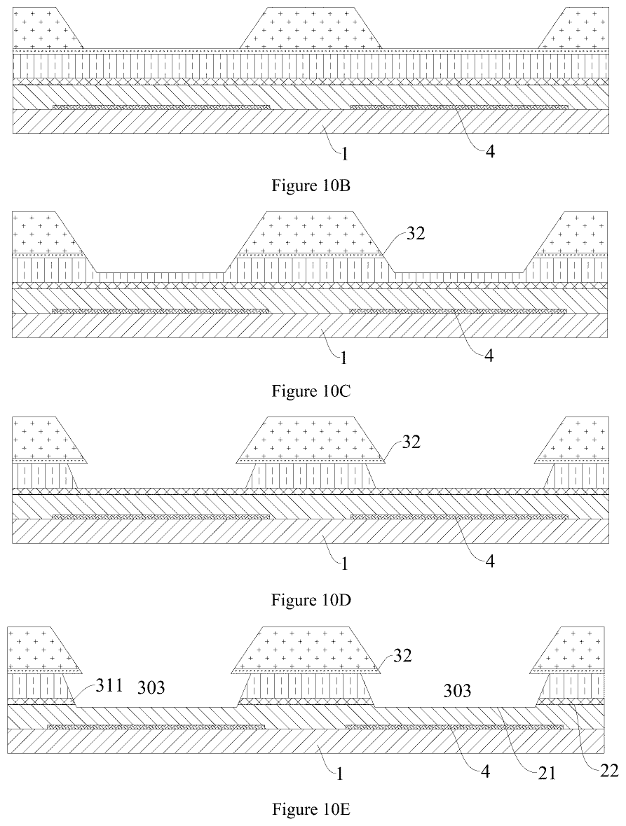

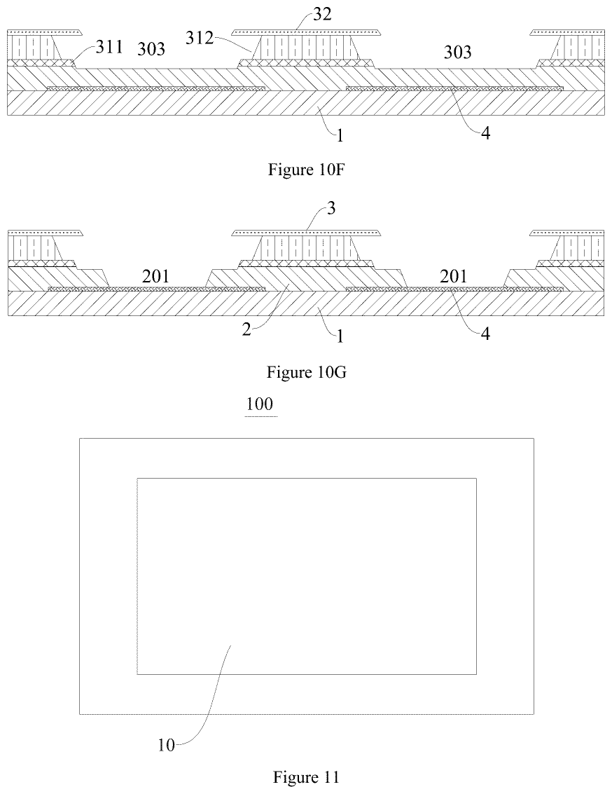

Please refer to FIG. 10A. In step S101, preparing the first support material layer on the side of the pixel definition material layer away from the substrate 1 includes:
Depositing one of titanium nitride and molybdenum nitride on the side of the pixel definition material layer away from the substrate 1 as the first support material layer.

This material can be patterned by dry etching to obtain a first support portion 311 that meets the design requirements.

In the above step S2, the isolation material layer is etched and patterned to form an isolation structure 3, which encloses a plurality of isolation openings 303, including:
Step S201, etching and patterning the crown material layer to obtain a crown portion 32;
Step S202, etching and patterning the second support material layer to obtain a second support portion 312;
Step S203, etching and patterning the first support material layer to obtain a first support portion 311;
The first support portion 311, the second support portion 312, and the crown portion 32 together form the isolation structure 3, and the first support portion 311, the second support portion 312, and the crown portion 32 enclose the plurality of isolation openings 303.

In some embodiments, the above step S3, etching and patterning the pixel definition material layer to form a first pixel definition portion 21 and a second pixel definition portion 22, includes:
Step S31, performing dry etching on the pixel definition material layer, wherein the pixel definition material layer located between the first support portion 311 and the substrate 1 forms the second pixel definition portion 22, and the remaining pixel definition material layer forms the first pixel definition portion 21.

The thickness of the first pixel definition portion 21 is less than that of the second pixel definition portion 22.

In step S31, during the processing of the pixel definition material layer, the first pixel definition portion 21 exposed relative to the isolation openings 303 is thinned by etching, so the thickness of the first pixel definition portion 21 is less than that of the second pixel definition portion 22.

In some embodiments, the orthographic projection of the first pixel definition portion 21 prepared by etching on the substrate 1 is located outside the orthographic projection of the first support portion 311 on the substrate 1.

Specifically, the first pixel definition portion 21 includes a first sub-portion 211 and a second sub-portion 212, the second sub-portion 212 is located between the first sub-portion 211 and the second pixel definition portion 22, the side of the first sub-portion 211 facing away from the substrate 1 is a first surface 21101, and the side of the second sub-portion 212 facing away from the substrate 1 is a second surface 21201; in a direction perpendicular to the plane of the substrate 1, the distance from the second surface 21201 to the substrate 1 is a first distance, and the distance from the first surface 21101 to the substrate 1 is a third distance, with the third distance being less than the first distance.

Specifically, the orthographic projection of the second sub-portion 212 on the substrate 1 is located outside the orthographic projection of the first support portion 311 on the substrate 1.

Specifically, the orthographic projection of the second sub-portion 212 on the substrate 1 at least partially overlaps with the orthographic projection of the crown portion 32 on the substrate 1.

In some embodiments, the above step S203, etching and patterning the first support material layer to obtain the first support portion 311, includes:
Performing dry etching on the first support material layer to obtain the first support portion 311.

In actual processing, in the above step S203 and step S31, the etching processes for the two different film layers are not clearly distinguished and can be understood as being performed sequentially or simultaneously in chronological order.

The thickness of the first support material layer is relatively thin, so during its etching process, part of the first support material layer may be etched through while another part remains unetched. To ensure that the first support material layer is completely etched to obtain the first support portion 311, the etching time for the first support material layer can be extended. During this etching process, the first pixel definition portion 21 located below the first support material layer to be etched away is gradually exposed as the etching proceeds and is subjected to excessive dry etching until part of the film layer is etched away, resulting in a thinned first pixel definition portion 21. The thinned portion of the first pixel definition portion 21 corresponds to and is located below the etched-away portion of the first support material layer (taking the orientation shown in the drawings as an example).

In some embodiments, step S202, etching and patterning the second support material layer to obtain the second support portion 312, includes:
Step S2021, performing a first wet etching on the second support material layer before etching and patterning the first support material layer;
Step S2022, performing a second wet etching on the second support material layer after etching and patterning the first support material layer, to obtain the second support portion 312.

Specifically, the above step S2021 further includes: performing dry etching on the second support material layer after etching and patterning the crown material layer to obtain the crown portion 22.

The above crown material layer can be prepared into the crown portion 22 through dry etching.

After the dry etching of the second support layer is completed, wet etching is performed on it, as recorded in step S2021, performing the first wet etching on the second support material layer before etching and patterning the first support material layer.

That is, step S2021 includes both dry etching and wet etching, and step S2022 includes wet etching. In other words, the second support material layer is etched using both dry etching and wet etching methods. In actual preparation, the second support material layer is sequentially subjected to dry etching, wet etching, and secondary wet etching for patterning to prepare the second support portion 312.

In some embodiments, the above step S3 further includes:
Step S32, etching and patterning the first pixel definition portion 21 a plurality of pixel openings 201, with the second pixel definition portion 22 located on the side of the first pixel definition portion 21 facing away from the pixel opening 201.

Specifically, the above first pixel definition portion 21 encloses the plurality of pixel openings 201.

The etching process for the isolation material layer and the pixel definition material layer in this preparation method is as follows:

First, prepare the film layer structure as shown in FIG. 10A, then form a photoresist on the surface of the crown material layer facing away from the substrate 1, and perform a patterning process on the photoresist to form the required photoresist pattern, please refer to FIG. 10B. Using the photoresist as a mask, etch the surface of the display panel 10 to remove the portions not covered by the photoresist.

In step S201, the crown material layer is etched by dry etching to form the crown portion 32. In step S2021, the second support material layer is first etched by dry etching to obtain the structure shown in FIG. 10C, and then the second support material layer is etched by wet etching until the first support material layer is exposed relative to the second support material layer. At this point, the second support material layer is prelimarily patterned. Please refer to FIG. 10D. Subsequently, step S203 is performed, in which the first support material layer is etched by dry etching to form the first support portion 311. Step S31 is then carried out, during which the first pixel definition portion 21 is thinned. Additionally, step S31 can remove any residual portions of the first support material layer that may remain on the surface of the first pixel definition portion 21. Please refer to FIG. 10E.

After step S31, the residual photoresist pattern can be removed, and step S2022 is performed to conduct a second wet etching of the second support material layer. At this stage, the sidewall of the second support material layer near the isolation opening 303 can shift away from the isolation opening 303 relative to the first support portion 311, resulting in the formation of the second support portion 312. Please refer to FIG. 10F.

The isolation structure 3 formed by the above preparation method encloses and forms the isolation openings 303, and the cross-section of the isolation structure 3 near the isolation opening 303 exhibits an overhanging shape.

Subsequently, after the isolation openings 303 is formed in the isolation structure 3, step S32 is executed to etch and pattern the first pixel definition portion 21 to form the pixel openings 201. The second pixel definition portion 22 is located on the side of the first pixel definition portion 21 opposite to the pixel openings 201. Please refer to FIG. 10G.

It can be understood that the preparation method of the display panel 10 provided in the embodiments of this application can thin the pixel definition layer 2 with the isolation structure 3. By adjusting the thinning of the film layer thickness on the side of the pixel definition layer 2 near the pixel opening 201, the defect of residual isolation structure 3 on the surface of the pixel definition layer 2 can be eliminated. This improves the display effect of the display panel 10, reduces the likelihood of display abnormalities caused by residual isolation structure 3, and helps enhance the reliability and performance of the display panel 10.

In a third aspect, this application also provides a display device 100. Please refer to FIG. 11. The display device 100 includes the aforementioned display panel 10.

The display device 100 provided in the embodiments of this application can be a product or component with display functionality, such as a mobile phone, notebook, tablet computer, smartwatch, smart bracelet, navigator, display, or Personal Digital Assistant (PDA). Since the display panel 10 in the display device 100 has the beneficial effects of any one or more of the aforementioned display panels 10, the specific effects are referenced in the detailed descriptions of the preceding embodiments and will not be reiterated here.

The above descriptions are merely preferred embodiments of this application and are not intended to limit this application. Any modifications, equivalent replacements, and improvements made within the spirit and principles of this application should be included within the scope of protection of this application.

What is claimed is:

1. A display panel, comprising:
a substrate;
a pixel definition layer located on one side of the substrate, the pixel definition layer comprising a first pixel definition portion and a second pixel definition portion, the first pixel definition portion enclosing a plurality of pixel openings, and the second pixel definition portion located on a side of the first pixel definition portion away from the plurality of pixel openings; and
an isolation structure located on a side of the pixel definition layer away from the substrate, the isolation structure comprising a first end portion and a second end portion, the first end portion contacting a surface of the second pixel definition portion away from the substrate, the second end portion located on a side of the first end portion away from the substrate, and the isolation structure enclosing a plurality of isolation openings, the pixel opening being located within the isolation opening;
wherein, along a direction perpendicular to a plane of the substrate, a maximum distance from a surface of the first pixel definition portion away from the substrate to the substrate is a first distance, a distance from a surface of the second pixel definition portion away from the substrate to the substrate is a second distance, and the first distance is less than the second distance.

2. The display panel according to claim 1, wherein an orthographic projection of the first end portion on the substrate is located outside an orthographic projection of the first pixel definition portion on the substrate, wherein
the orthographic projection of the first end portion on the substrate overlaps with an orthographic projection of the second pixel definition portion on the substrate, or
the orthographic projection of the first end portion on the substrate is located within a range of the orthographic projection of the second pixel definition portion on the substrate.

3. The display panel according to claim 1, wherein an orthographic projection of the first end portion on the substrate is located within a range of an orthographic projection of the second end portion on the substrate; and
an orthographic projection of the first pixel definition portion on the substrate partially overlaps with the orthographic projection of the second end portion on the substrate.

4. The display panel according to claim 1, wherein the isolation structure comprises a support portion and a crown portion, the crown portion being located on a side of the support portion away from the substrate;
the first end portion is provided at an end of the support portion away from the crown portion, and the second end portion is provided at an end of the crown portion away from the support portion; and
an orthographic projection of the support portion on the substrate is located within a range of an orthographic projection of the crown portion on the substrate, and an orthographic projection of the first pixel definition portion on the substrate partially overlaps with the orthographic projection of the crown portion on the substrate.

5. The display panel according to claim 4, wherein the support portion comprises a first support portion and a second support portion, the second support portion being located on a side of the first support portion away from the substrate, and the first end portion is provided at an end of the first support portion away from the second support portion;
an orthographic projection of the second support portion on the substrate is located within a range of an orthographic projection of the first support portion on the substrate;
the orthographic projection of the first support portion on the substrate overlaps with an orthographic projection of the second pixel definition portion on the substrate, or the orthographic projection of the first support portion on the substrate is located within the range of the orthographic projection of the second pixel definition portion on the substrate; and
the orthographic projection of the first pixel definition portion on the substrate partially overlaps with the orthographic projection of the crown portion on the substrate.

6. The display panel according to claim 5, wherein a side of the first support portion close to the isolation opening has a first sidewall, and a portion of the second pixel definition portion away from the substrate and protruding relative to the first pixel definition portion has a second sidewall on a side close to the isolation opening, wherein
at least a portion of the first sidewall and at least a portion of the second sidewall on the same side of the isolation opening are connected and lie on a same plane; and
in a direction parallel to the plane of the substrate, a distance from a side of the same plane away from the substrate to an edge of the pixel opening is greater than a distance from a side of the same plane close to the substrate to the edge of the pixel opening, and the same plane forms an angle with a direction perpendicular to the plane of the substrate, the angle is between 0° and 90°.

7. The display panel according to claim 5, wherein the first pixel definition portion comprises a first sub-portion and a second sub-portion, the first sub-portion enclosing the pixel openings, and the second sub-portion located between the first sub-portion and the second pixel definition portion, a side of the first sub-portion away from the substrate being a first surface, and a side of the second sub-portion away from the substrate being a second surface; and
in a direction perpendicular to the plane of the substrate, a distance from the second surface to the substrate is the first distance, a distance from the first surface to the substrate is a third distance, and the third distance is less than the first distance.

8. The display panel according to claim 7, wherein an orthographic projection of the first sub-portion on the substrate is located outside an orthographic projection of the isolation structure on the substrate;
an orthographic projection of the second sub-portion on the substrate is located outside an orthographic projection of the first end portion on the substrate;
the orthographic projection of the second sub-portion on the substrate is located outside the orthographic projection of the first support portion on the substrate;
the orthographic projection of the second sub-portion on the substrate at least partially overlaps with an orthographic projection of the second end portion on the substrate; and
the orthographic projection of the second sub-portion on the substrate at least partially overlaps with the orthographic projection of the crown portion on the substrate.

9. The display panel according to claim 5, wherein the display panel further comprises a first electrode layer, the first electrode layer is located between the substrate and the pixel definition layer, at least a portion of the first electrode layer is exposed through the pixel opening, and an orthographic projection of the first electrode layer on the substrate at least partially overlaps with an orthographic projection of the support portion on the substrate;
the orthographic projection of the first pixel definition portion on the substrate is located within a range of the orthographic projection of the first electrode layer on the substrate; and
the orthographic projection of the first electrode layer on the substrate partially overlaps with the orthographic projection of the second pixel definition portion on the substrate.

10. The display panel according to claim 9, wherein the display panel further comprises a light-emitting functional layer disposed in the isolation opening, the light-emitting functional layer is located on a side of the first electrode layer away from the substrate; and
an orthographic projection of the pixel opening on the substrate is located within a range of an orthographic projection of the light-emitting functional layer on the substrate.

11. The display panel according to claim 10, wherein the display panel further comprises a second electrode layer disposed in the isolation opening, the second electrode layer is located on a side of the light-emitting functional layer facing away from the substrate, and the second electrode layer contacts with at least a portion of a sidewall of the isolation structure facing the isolation opening.

12. The display panel according to claim 11, wherein the display panel further comprises an encapsulation layer, at least a portion of the encapsulation layer is located in the isolation opening and covers the second electrode layer; the encapsulation layer comprises a plurality of spaced encapsulation units, each encapsulation unit comprising:
a first encapsulation portion located on a side of the second electrode layer facing away from the substrate;
a second encapsulation portion located on a side of the isolation structure facing away from the substrate; and
a third encapsulation portion covering a sidewall of the isolation structure facing the corresponding isolation opening;
wherein the third encapsulation portion connects the first encapsulation portion and the second encapsulation portion.

13. A method for preparing a display panel, comprising:
forming a pixel definition material layer on one side of a substrate, and forming an isolation material layer on a side of the pixel definition material layer facing away from the substrate;
etching and patterning the isolation material layer to form an isolation structure, wherein the isolation structure encloses a plurality of isolation openings; and
etching and patterning the pixel definition material layer to form a first pixel definition portion and a second pixel definition portion, wherein the first pixel definition portion encloses a plurality of pixel openings, and the second pixel definition portion is located on a side of the first pixel definition portion facing away from the plurality of pixel openings; wherein
the pixel opening is located within the isolation opening, the isolation structure comprises a first end portion and a second end portion, the first end portion contacts a surface of the second pixel definition portion facing away from the substrate, and the second end portion is located on a side of the first end portion facing away from the substrate; and
along a direction perpendicular to a plane of the substrate, a maximum distance from a surface of the first pixel definition portion away from the substrate to the substrate is a first distance, a distance from a surface of the second pixel definition portion away from the substrate to the substrate is a second distance, and the first distance is less than the second distance.

14. The method according to claim 13, wherein the forming an isolation material layer on a side of the pixel definition material layer facing away from the substrate comprises:
forming a first support material layer on the side of the pixel definition material layer facing away from the substrate;
forming a second support material layer on a side of the first support material layer facing away from the substrate; and
forming a crown material layer on a side of the second support material layer facing away from the substrate.

15. The method according to claim 14, wherein the etching and patterning the isolation material layer to form an isolation structure comprises:
etching and patterning the crown material layer to form a crown portion;
etching and patterning the second support material layer to form a second support portion; and
etching and patterning the first support material layer to form a first support portion;
wherein, the first support portion, the second support portion, and the crown portion constitute the isolation structure, and the first support portion, the second support portion, and the crown portion enclose the isolation openings.

16. The method according to claim 15, wherein the etching and patterning the pixel definition material layer to form a first pixel definition portion and a second pixel definition portion comprises:
dry etching the pixel definition material layer, wherein a portion of the pixel definition material layer located between the first support portion and the substrate forms the second pixel definition portion, and the remaining portion of the pixel definition material layer forms the first pixel definition portion; wherein
an orthographic projection of the first pixel definition portion on the substrate is located outside an orthographic projection of the first support portion on the substrate;
the first pixel definition portion comprises a first sub-portion and a second sub-portion, the second sub-portion is located between the first sub-portion and the second pixel definition portion, a side of the first sub-portion facing away from the substrate is a first surface, and a side of the second sub-portion facing away from the substrate is a second surface; in a direction perpendicular to the plane of the substrate, a distance from the second surface to the substrate is the first distance, a distance from the first surface to the substrate is a third distance, and the third distance is less than the first distance;
an orthographic projection of the second sub-portion on the substrate is located outside the orthographic projection of the first support portion on the substrate; and
the orthographic projection of the second sub-portion on the substrate at least partially overlaps with an orthographic projection of the crown portion on the substrate.

17. The method according to claim 16, wherein the etching and patterning the first support material layer to form a first support portion comprises:
dry etching the first support material layer.

18. The method according to claim 15, wherein the etching and patterning the second support material layer to form a second support portion comprises:
performing a first wet etching on the second support material layer before etching and patterning the first support material layer; and
performing a second wet etching on the second support material layer after etching and patterning the first support material layer to form the second support portion.

19. The method according to claim 14, wherein the preparing a first support material layer on a side of the pixel definition material layer away from the substrate comprises:
depositing one of titanium nitride and molybdenum nitride on the side of the pixel definition material layer away from the substrate as the first support material layer.

20. A display device, comprising:
a display panel, comprising:
a substrate;
a pixel definition layer located on one side of the substrate, the pixel definition layer comprising a first pixel definition portion and a second pixel definition portion, the first pixel definition portion enclosing a plurality of pixel openings, and the second pixel definition portion located on a side of the first pixel definition portion away from the plurality of pixel openings; and
an isolation structure located on a side of the pixel definition layer away from the substrate, the isolation structure comprising a first end portion and a second end portion, the first end portion contacting a surface of the second pixel definition portion away from the substrate, the second end portion located on a side of the first end portion away from the substrate, and the isolation structure enclosing a plurality of isolation openings, the pixel opening being located within the isolation opening;
wherein, along a direction perpendicular to a plane of the substrate, a maximum distance from a surface of the first pixel definition portion away from the substrate to the substrate is a first distance, a distance from a surface of the second pixel definition portion away from the substrate to the substrate is a second distance, and the first distance is less than the second distance.
